(19) United States
(12) Patent Application Publication
(10) Pub. No.: US 2006/0041805 A1
(43) Pub. Date: Feb. 23, 2006

(54) Array substrate, display device having the same, driving unit for driving the same and method of driving the same

(76) Inventor: Jang-Kun Song, Seoul (KR)

Correspondence Address: CANTOR COLBURN, LLP, 55 GRIFFIN ROAD SOUTH, BLOOMFIELD, CT, 06002, US

(21) Appl. No.: 11/184,381

(22) Filed: Jul. 19, 2005

(30) Foreign Application Priority Data
Jul. 27, 2004 (KR) 2004-58850

(51) Int. Cl. G01R 31/28

(52) U.S. Cl. 714/724

(57) ABSTRACT

An array substrate of an N-line inversion type includes data lines, scan lines and pixels. A number of the data lines is ‘m’, and the data lines are extended in a first direction. A number of the scan lines is ‘n’, and the scan lines are extended in a second direction that is substantially perpendicular to the first direction. Each of the scan lines has a contact terminal that makes contact with corresponding ones of output terminals of a scan driving part that generates scan signals. A K(N+1)-th output terminal is disconnected from the scan lines. The number of the pixels is ‘m times n’. The pixels are formed in regions defined by the data and scan lines. m, n, K and N are each natural numbers. Therefore, a charging rate of each of inverted horizontal lines increases.

This application claims priority to Korean Patent Application No. 2004-58850, filed on Jul. 27, 2004, and all the benefits accruing therefrom under 35 U.S.C §119, and the contents of which in its entirety are herein incorporated by reference.

### BACKGROUND OF THE INVENTION

1. Field of the Invention

The present invention relates to an array substrate, a display device having the array substrate, a driving unit for driving the display device and a method of driving the display device. More particularly, the present invention relates to an array substrate capable of improving a charging rate, a display device having the array substrate, a driving unit for driving the display device and a method of driving the display device.

2. Description of the Related Art

A conventional liquid crystal display (LCD) device includes an LCD panel and a driving part that drives the LCD panel. The LCD panel includes an array substrate, an upper substrate and a liquid crystal layer disposed between the array substrate and the upper substrate.

The array substrate includes data lines, scan lines and pixels. The data lines cross the scan lines. Each of the pixels is defined by the data and scan lines adjacent to each other.

A switching element, a liquid crystal capacitor and a storage capacitor are included in each of the pixels. A gate electrode of the switching element is electrically connected to a corresponding one of the scan lines. A source electrode of the switching element is electrically connected to a corresponding one of the data lines. A drain electrode of the switching element is electrically connected to a pixel electrode that is a first electrode of the liquid crystal capacitor. The storage capacitor is formed by the gate electrode and the pixel electrode.

The upper substrate includes a color filter corresponding to each of the pixels and a common electrode that is a second electrode of the liquid crystal capacitor. When a voltage having a predetermined polarity is continuously applied to the first and second electrodes adjacent to a liquid crystal of the liquid crystal layer, the liquid crystal is deteriorated. Deterioration of the liquid crystal is prevented through an inversion method. In the inversion method, polarity of voltage applied to the first and second electrodes adjacent to the liquid crystal is inverted at a predetermined interval.

The inversion method is classified into a frame inversion type, a line inversion type, a dot inversion type, etc. In the frame inversion type, the polarity of the voltage applied to the first and second electrodes adjacent to the liquid crystal over all of the pixels is inverted in every frame. In the line inversion type, the polarity of the voltage applied to the first and second electrodes adjacent to the liquid crystal over pixels corresponding to each of the gate or data lines is inverted in every frame, and the polarity of voltages of the gate or data lines are different from one another. In the dot inversion type, the polarity of the voltage applied to the first and second electrodes adjacent to the liquid crystal over each of the pixels is inverted in every frame, and the polarity of the first and second electrodes are different from one another.

When the voltage applied to the first and second electrodes adjacent to the liquid crystal is inverted from a first polarity to a second polarity, a level of the voltage is dropped so that a charging rate of each of inverted horizontal lines is smaller than a charging rate of non-inverted horizontal lines.

When the charging rate of the inverted horizontal lines is decreased, a horizontal stripe is formed on a screen of the LCD device. For example, a bright horizontal stripe and a dark horizontal stripe are formed in a normally white mode and a normally black mode, respectively. In addition, when the LCD device has a high resolution and displays a moving image, an image display quality of the LCD device is decreased.

### SUMMARY OF THE INVENTION

The present invention provides an array substrate capable of improving a charging rate. The present invention further provides a display device having the above-mentioned array substrate. The present invention still further provides a driving unit for driving the above-mentioned display device. The present invention still further provides a method of driving the above-mentioned display device.

An array substrate of an N-line inversion type in accordance with an aspect of the present invention includes data lines, scan lines and pixels. A number of the data lines is ‘m’, and the data lines are extended in a first direction. A number of the scan lines is ‘n’, and the scan lines are extended in a second direction that is substantially perpendicular to the first direction. Each of the scan lines has a contact terminal that makes contact with corresponding ones of output terminals of a scan driving part that generates scan signals. A K(N+1)-th output terminal is disconnected from the scan lines. The number of the pixels is ‘m×n’ (m times n). The pixels are formed in regions defined by the data and scan lines. m, n, K and N are each natural numbers.

A display device in accordance with an aspect of the present invention includes a display part, a driving part, a scan driving part and a controlling part. The display part has data lines, scan lines and pixels. Each of the pixels is electrically connected to corresponding ones of the data lines and corresponding ones of the scan lines. The driving part outputs valid data signals that charge the pixels and an invalid data signal to the data lines. The scan driving part generates scan signals corresponding to the valid data signals and the invalid scan signal corresponding to the invalid data signal to output the scan signals to the scan lines. The scan signals activate the scan lines corresponding to the valid data signals. The controlling part controls the data driving part so that the data driving part outputs N valid data signals having a first polarity, an invalid data signal having a second polarity and N valid data signals having the second polarity to the data lines, in sequence. The second polarity is opposite to the first polarity with respect to a reference voltage.

A driving unit for driving a display device in accordance with an aspect of the present invention includes a driving part, a scan driving part and a controlling part. The display device includes a display part having data lines, scan lines and pixels electrically connected to the data and scan lines. The driving part outputs valid data signals that charge the pixels and invalid data signal to the data lines. The scan driving part generates scan signals corresponding to the valid data signals and an invalid scan signal corresponding to the invalid data signal to output the scan signals to the scan lines. The scan signals activate the scan lines corresponding to the valid data signals. The controlling part controls the data driving part so that the data driving part outputs N valid data signals having a first polarity, an invalid data signal having a second polarity and N valid data signals having the second polarity to the data lines, in sequence or in a first-in first out manner. The second polarity is opposite to the first polarity with respect to a reference voltage.

A method of driving a display in accordance with an aspect of the present invention is provided as follows. The display device includes a display part having data lines, scan lines and pixels electrically connected to the data and scan lines. N valid data signals to the data lines is applied, and scan signals are applied to the scan lines corresponding to the N valid data signals to activate the scan lines corresponding to the N valid data signals using an N-line inversion method. The N valid data signals have a first polarity. An invalid data signal is applied to one of the data lines after the N valid data signals, and an invalid scan signal is applied to one of the scan lines corresponding to the invalid data signal to deactivate the one of the scan lines corresponding to the invalid data signal. The invalid data signal has a second polarity that is opposite to the first polarity with respect to a reference voltage.

Therefore, the charging rate of each of inverted horizontal lines increases.

### BRIEF DESCRIPTION OF THE DRAWINGS

The above and other advantages of the present invention will become more apparent by describing in detail exemplary embodiments thereof with reference to the accompanying drawings, in which:

FIG. 1 is a plan view showing an N-line-dot inversion method in accordance with an exemplary embodiment of the present invention;

FIG. 2 is a timing diagram showing a charging rate of an inverted pixel that is inverted through the N-line inversion method of FIG. 1;

FIG. 3 is a block diagram showing a liquid crystal display (LCD) device in accordance with an exemplary embodiment of the present invention;

FIG. 4 is a block diagram showing an exemplary driving unit of the LCD device of FIG. 3;

FIG. 5 is a timing diagram showing a method of driving the driving unit of FIG. 4;

FIG. 6 is a timing diagram showing a method of driving a driving unit in accordance with another exemplary embodiment of the present invention;

FIG. 7 is a block diagram showing a driving unit of an LCD device in accordance with another exemplary embodiment of the present invention;

FIG. 8 is a timing diagram showing a method of driving a driving unit in accordance with another exemplary embodiment of the present invention;

FIG. 9 is a timing diagram showing a method of driving a driving unit in accordance with another exemplary embodiment of the present invention;

FIG. 10 is a plan view showing an exemplary scan driving part of FIG. 3;

FIG. 11 is a plan view showing another exemplary scan driving part of FIG. 3;

FIG. 12 is a plan view showing another exemplary scan driving part of FIG. 3; and

FIG. 13 is a plan view showing another exemplary scan driving part of FIG. 3.

### DETAILED DESCRIPTION OF THE INVENTION

It should be understood that the exemplary embodiments of the present invention described below may be modified in many different ways without departing from the inventive principles disclosed herein, and the scope of the present invention is therefore not limited to these particular following embodiments. Rather, these embodiments are provided so that this disclosure will be through and complete, and will fully convey the concept of the invention to those skilled in the art by way of example and not of limitation.

Hereinafter, the present invention will be described in detail with reference to the accompanying drawings.

FIG. 1 is a plan view showing an N-line-dot inversion method in accordance with an exemplary embodiment of the present invention.

Referring to FIG. 1, a polarity of a voltage applied to pixels in every N-th line is inverted. In this exemplary embodiment, the polarity of the voltage applied to the pixels in every 4-th line is inverted.

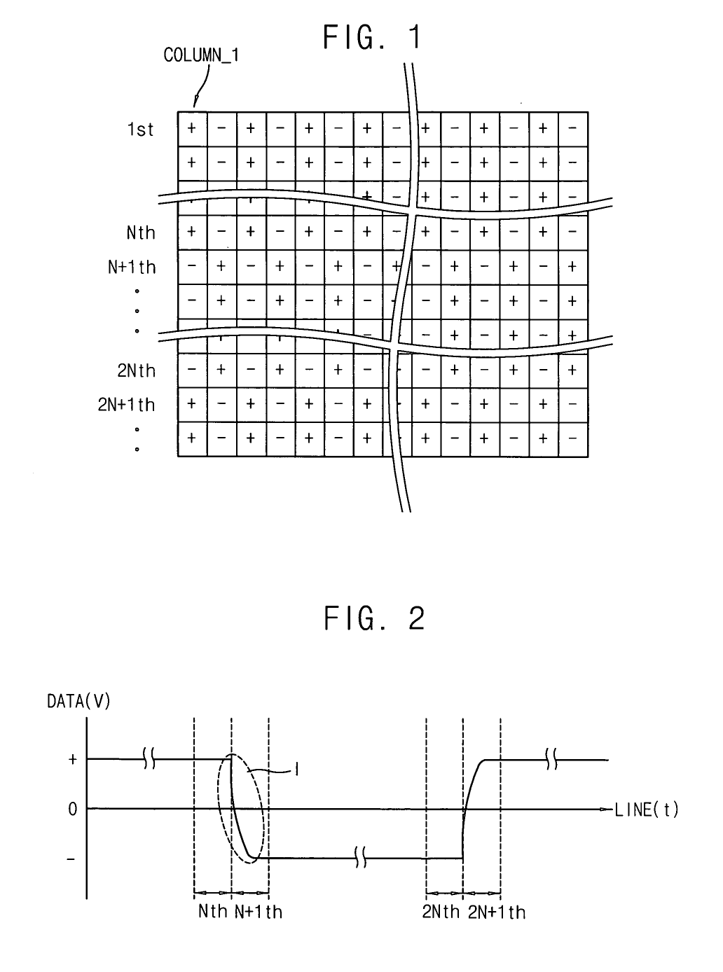

FIG. 2 is a timing diagram showing a charging rate of an inverted pixel that is inverted through the N-line-dot inversion method of FIG. 1.

Referring to FIG. 2, pixels in a first column COLUMN_1 are charged by data signals from a first date line.

A data signal having a first polarity that is a positive polarity is applied to first to N-th horizontal lines. In addition, a data signal having a second polarity that is a negative polarity is applied to (N+1)-th to 2N-th horizontal lines. Furthermore, a data signal having the first polarity that is the positive polarity is applied to the (2N+1)-th to 3N-th horizontal lines. In other words, a polarity of the data signal is inverted in every N-th horizontal lines. As shown in oval portion I of FIG. 2, a charging delay exists as polarity applied to the horizontal lines switches from positive to negative polarity or from negative to positive polarity.

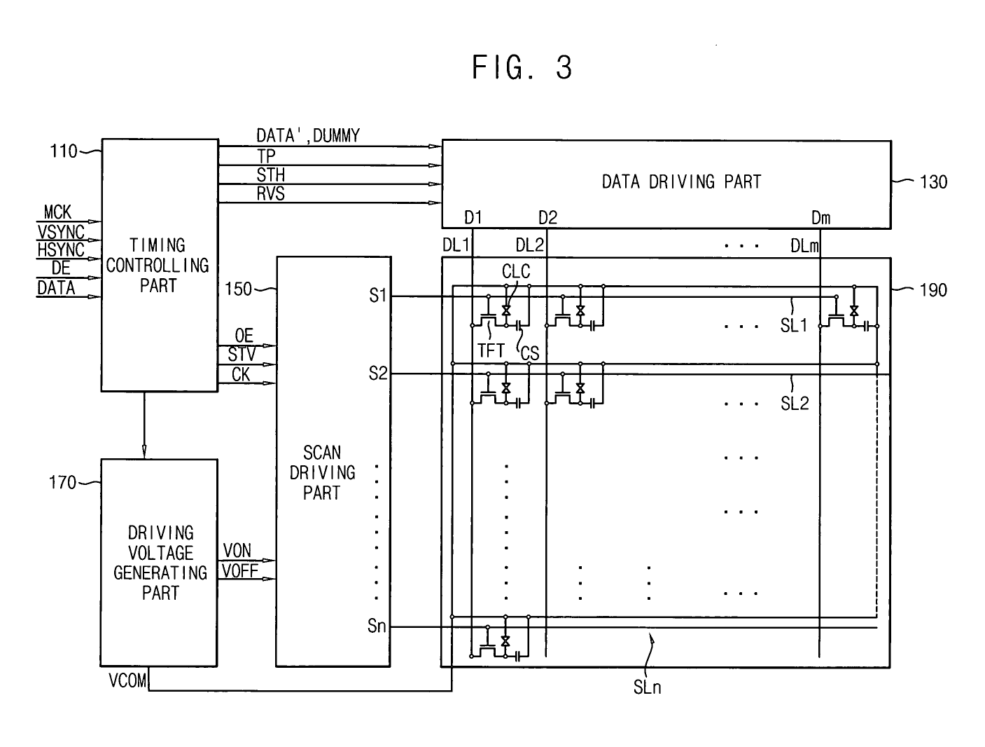

FIG. 3 is a block diagram showing a liquid crystal display (LCD) device in accordance with an exemplary embodiment of the present invention.

Referring to FIG. 3, the LCD device includes a timing controlling part 110, a data driving part 130, a scan driving part 150, a driving voltage generating part 170 and an LCD panel 190.

The timing controlling part 110 processes data signals DATA from an external graphic unit (not shown) to output processed data signals DATA′ to the data driving part 130.

When a number of scan lines is ‘n’, the timing controlling part 110 further outputs dummy data signals DUMMY to the data driving part 130 so as to decrease a difference between charging rates of the pixels. In this exemplary embodiment, the dummy data signals DUMMY are a predetermined data signal. Alternatively, the dummy data signals DUMMY may be a previous data signal. When n is a multiple of N, a number of the dummy data signals DUMMY is n/N−1. When n is not a multiple of N, the number of the dummy data signals DUMMY is a truncated integer of n/N without decimals. Alternatively, the number of the dummy data signals DUMMY may be n/N although n is a multiple of N.

For example, the timing controlling part 110 outputs a data signal having the first polarity, one of the dummy data signals DUMMY having the second polarity and a data signal having the second polarity, in sequence, so that the charging rate is controlled by the dummy data signal DUMMY. For example, when the number of the scan lines is 800, and the polarity of the data signals is inverted in every 128th horizontal lines, the timing controlling part 110 outputs six dummy data signals DUMMY after the data signals corresponding to 128th scan line, (128×2+1)-th scan line, (128×3+2)-th scan line, (128×4+3)-th scan line, (128×5+4)-th scan line and (128×6+5)-th scan line are outputted from the timing controlling part 110, respectively. The six dummy data signals DUMMY may be applied to the scan lines. In this exemplary embodiment, the six dummy data signals DUMMY are applied to the data signals corresponding to (128+1)-th scan line, (128×2+2)-th scan line, (128×3+3)-th scan line, (128×4+4)-th scan line, (128×5+5)-th scan line and (128×6+6)-th scan line, respectively. Alternatively, the six dummy data signals DUMMY may not be applied to the scan lines. A truncated integer of 800/128 without decimals is 6. Each of the dummy data signals DUMMY is inverted from each of the data signals corresponding to (128+1)-th scan line, (128×2+2)-th scan line, (128×3+3)-th scan line, (128×4+4)-th scan line, (128×5+5)-th scan line and (128×6+6)-th scan line, respectively.

The dummy data signals DUMMY are inserted between the data signals so that a portion of the data signals are delayed by the dummy data signals DUMMY. The delayed data signals are outputted during a vertical blanking period.

The timing controlling part 110 outputs second to fourth control signals based on a first control signal that is provided by the external graphic unit. The first control signal includes a main clock signal MCLK, a horizontal synchronization signal HSYNC, a vertical synchronization signal VSYNC and a data enable signal DE. The second control signal includes a horizontal start signal STH, an inversion signal RVS and a load signal TP. The second control signal controls the data driving part 130. The third control signal includes a main clock signal, an inversion signal, etc. The third control signal controls the driving voltage generating part 170. The fourth control signal includes a scan start signal STV, a clock signal CK, an output enable signal OE, etc. The fourth control signal controls the scan driving part 150.

The data driving part 130 converts the data signals into analog data signals D1, D2, . . . Dm responsive to the second control signal to output the analog data signals D1, D2, . . . Dm to data lines DL1, DL2, . . . DLm. The data driving part 130 outputs n valid data signals that correspond to the n scan lines and the dummy data signals DUMMY that are invalid data signals through an N-line inversion method.

The scan driving part 150 generates scan signals responsive to the fourth control signal to output the scan signals to the scan lines. The scan signals include n scan signals that correspond to the n scan lines and dummy scan signals that correspond to the dummy data signals DUMMY. When n is a multiple of N, the number of the dummy scan signals is n/N−1. When n is not a multiple of N, the number of the dummy scan signals is a truncated integer of n/N without decimals. Alternatively, the number of the dummy signals DUMMY may be n/N although n is a multiple of N.

For example, one of the dummy scan signals SD is inserted between N-th scan signal SN and (N+1)-th scan signal SN+1. When the N-th data signal having the first polarity is applied to the Nth data line, the N-th scan signal SN is applied to the N-th scan line SLn so that the N-th scan line SLn is activated.

The dummy scan signals SD are not applied to the scan lines, although the dummy data signals DUMMY are applied to the data lines. The dummy data signals DUMMY are not stored in the pixels of the LCD panel 190. Therefore, the charging rate is not deteriorated although the polarity of the signals is inverted.

The driving voltage generating part 170 generates a first voltage VOFF, a second voltage VON and a common voltage VCOM. The first and second voltages VOFF and VON are applied to the scan driving part 150. The common voltage VCOM is applied to a liquid crystal capacitor CLC and a storage capacitor CS of the LCD panel 190.

The LCD panel 190 includes an array substrate, an upper substrate and a liquid crystal layer interposed between the array substrate and the upper substrate.

The array substrate includes the data lines DL1, DL2, . . . DLm, the scan lines SL1, SL2, . . . SLn and pixels. Each of the pixels is defined by the data and scan lines adjacent to each other. A number of the pixels is m×n (m times n).

A switching element that includes a thin film transistor TFT, the liquid crystal capacitor CLC and the storage capacitor CS is included in each of the pixels. A gate electrode of the switching element is electrically connected to a corresponding one of the scan lines SL1, SL2, . . . SLn. A source electrode of the switching element is electrically connected to a corresponding one of the data lines DL1, DL2, . . . DLm. A drain electrode of the switching electrode is electrically connected to a pixel electrode that is a first electrode of the liquid crystal capacitor CLC. The storage capacitor CS is defined by the gate electrode of the switching element and the pixel electrode.

The upper substrate includes a color filter and a common electrode that is a second electrode of the liquid crystal capacitor CLC. The color filter corresponds to each of the pixels. The common voltage VCOM from the driving voltage generating part 170 is applied to the common electrode and the storage capacitor CS and the liquid crystal capacitor CLC.

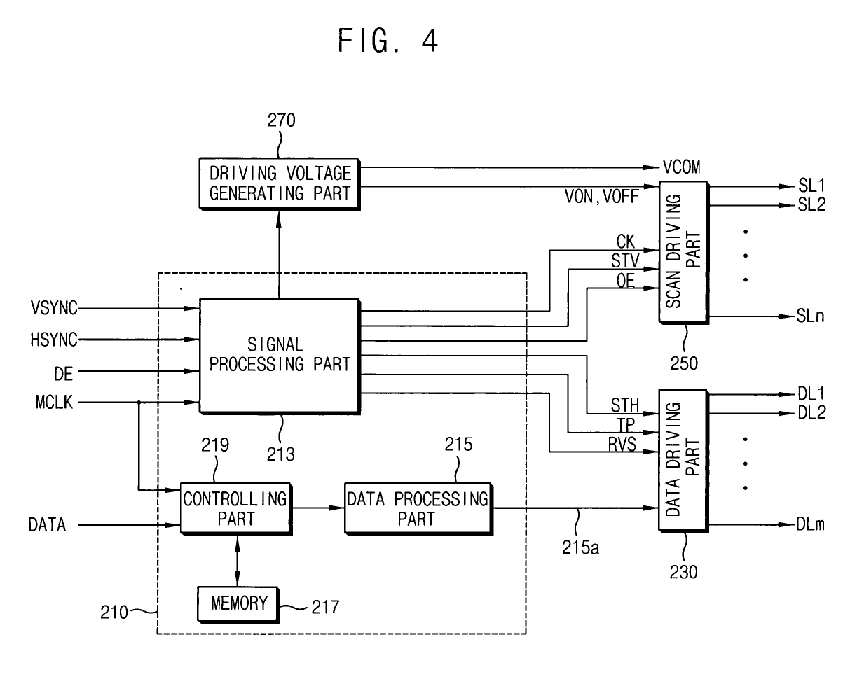

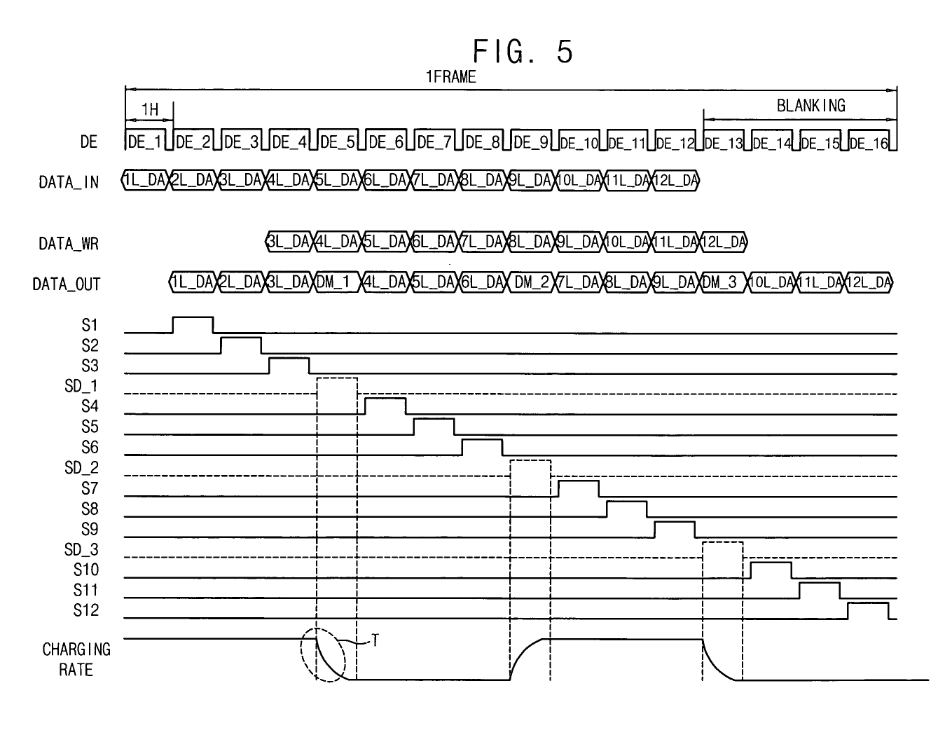

FIG. 4 is a block diagram showing an exemplary driving unit of the LCD device of FIG. 3.

Referring to FIG. 4, the driving unit includes a timing controlling part 210, a data driving part 230, a scan driving part 250 and a driving voltage generating part 270.

The timing controlling part 210 includes a signal processing part 213, a data processing part 215, a memory 217 and a controlling part 219.

The signal processing part 213 generates control signals responsive to signals from exterior to the driving unit. The control signals generated by the signal processing part 213 are applied to the data driving part 230, the scan driving part 250 and the driving voltage generating part 270, respectively.

For example, the signal processing part 213 outputs the control signals to the data driving part 230, the scan driving part 250 and the driving voltage generating part 270 responsive to the vertical synchronization signal VSYNC, the horizontal synchronization signal HSYNC, the data enable signal DE and the main clock signal MCLK, which are provided by an external graphic controller (not shown). Frames of the driving unit are controlled responsive to the vertical synchronization signal VSYNC. Horizontal lines of the driving unit are controlled responsive to the horizontal synchronization signal HSYNC. The data enable signal DE enables the signal processing part 213 to generate a signal having a high level while processing data signals. For example, the signal processing part 213 generates the horizontal start signal STH, the load signal TP, the scan clock CK, the vertical start signal STV that is a scan start signal, the inversion signal RVS, a scan output enable signal OE that is a gate output enable signal, etc.

The data processing part 215 processes data signals DATA from the external graphic controller (not shown) through the controlling part 219, and processed data signals 215a are applied to the data driving part 230. The data processing part 215 may control timing of the data signals DATA.

A portion of the data signals DATA are delayed by a dummy data signal. The delayed portion of the data signals DATA are temporarily stored as stored data signals in the memory 217.

The controlling part 219 controls an operation of the driving unit. In addition, the controlling part 219 stores the delayed portion of the data signals DATA in the memory 217, and reads the stored data signals. The controlling part 219 outputs the stored data signals to the data driving part 230 during the vertical blanking period, in sequence. The vertical blanking period may be a latter portion of a frame.

The data driving part 230 outputs analog signals to the data lines DL1, DL2, . . . DLm responsive to the data signals DATA and the dummy data signals. The data signals DATA and the dummy data signals are outputted from the timing controlling part 210 responsive to the horizontal start signal STH, the load signal TP, the inversion signal RVS, etc.

The scan driving part 250 generates scan signals and the dummy data signals responsive to control signals such as the scan start signal STV, the output enable signal OE, the scan clock signal CK, etc., and the first and second voltages VOFF and VON from the driving voltage generating part 270. The scan driving part 250 outputs the scan signals to the scan lines SL1, SL2, . . . SLn, and does not output the dummy scan signals to the scan lines SL1, SL2, . . . SLn.

The driving voltage generating part 270 outputs the first and second voltages VOFF and VON to the scan driving part 250, and outputs the common voltage VCOM to the liquid crystal capacitor CLC of the LCD panel 190 and the common electrode of the storage capacitor CS.

FIG. 5 is a timing diagram showing a method of driving the driving unit of FIG. 4. As shown in FIG. 5, a number of the scan lines SL1, SL2, . . . SLn of the driving unit is twelve, and thus timing diagrams for corresponding scan signals S1 to S12 are shown. A unit frame is 16H, and each frame has a vertical blanking period of 4H. The driving unit is operated through a 3-line inversion method.

Referring to FIGS. 3, 4 and 5, first to twelfth line data signals 1L_DA to 12L_DA, shown by data signals DATA_IN, are applied to the first to twelfth data lines DL1 to DL12 of the driving unit responsive to the data enable signal DE during the unit frame, in sequence.

The first line data signal 1L_DA is processed by the data processing part 215 and the data driving part 230 so that the first line data signal 1L_DA has a first polarity with respect to a reference voltage level. Following processing, the first line data signal 1L_DA is synchronized with a second data enable pulse DE_2. The synchronized first line data signal 1L_DA is applied to the first data line DL1 as a portion of the data signals DATA_OUT.

Second and third line data signals 2L_DA and 3L_DA are synchronized with third and fourth data enable pulses DE_3 and DE_4, respectively, so that the synchronized second and third line data signals 2L_DA and 3L_DA are applied to the second and third data lines DL2 and DL3, in sequence.

When the first, second and third line data signals 1L_DA, 2L_DA and 3L_DA are applied to the first, second and third data lines DL1, DL2 and DL3, the scan driving part 250 outputs the first, second and third scan signals S1, S2 and S3 to the first, second and third scan lines SL1, SL2 and SL3, in sequence.

The controlling part 219 outputs the first dummy data signal DM_1 to the data driving part 230 after the third line data signal 3L_DA using the 3-line inversion method. The first dummy data signal DM_1 may be data stored in the memory 217 or a previous line data signal such as the third line data signal 3L_DA.

The controlling part 219 stores a fourth line data signal 4L_DA in the memory 217 while the controlling part 219 outputs the first dummy data signal DM_1. The data driving part 230 processes the first dummy data signal DM_1 so that the first dummy data signal DM_1 has a second polarity with respect to the reference voltage level. The second polarity is opposite to the first polarity. The first dummy data signal DM_1 having the second polarity may be applied to one of the data lines DL1 to DL12. Alternatively, the first dummy data signal DM_1 having the second polarity may not be applied to one of the data lines DL1 to DL12. Here, the scan driving part 250 generates a first dummy scan signal SD_1. However, the first dummy scan signal SD_1 is not applied to the scan lines SL1 to SL12 so that the first dummy data signal DM_1 does not charge a pixel of the LCD panel 190 although the first dummy data signal DM_1 is applied to one of the data lines DL1 to DL12. The controlling part 219 reads the stored fourth line data signal 4L_DA to output the fourth line data signal 4L_DA to the data driving part 230. The controlling part 219 stores a fourth line data signal 5L_DA in the memory 217 while the controlling part 219 reads the stored fourth line data signal. 4L_DA.

The fourth, fifth and sixth line data signals 4L_DA, 5L_DA and 6L_DA that have the second polarity are applied to the fourth, fifth and sixth data lines DL4, DL5 and DL6, and the fourth, fifth and sixth scan signals S4, S5 and S6 are applied to the fourth, fifth and sixth scan lines SL4, SL5 and SL6, respectively.

The seventh, eighth and ninth line data signals 7L_DA, 8L_DA and 9L_DA that have the first polarity are applied to the seventh, eighth and ninth data lines DL7, DL8 and DL9, and the seventh, eighth and ninth scan signals S7, S8 and S9 are applied to the seventh, eighth and ninth scan lines SL7, SL8 and SL9, respectively.

The controlling part 219 outputs the second dummy data signal DM_2 to the driving part 230 during the ninth data enable pulse DE_9. The seventh, eighth and ninth line data signals 7L_DA, 8L_DA and 9L_DA are synchronized with the second dummy data signal DM_2, and the synchronized seventh, eighth and ninth line data signals 7L_DA, 8L_DA and 9L_DA are applied to the driving part 230, in sequence or in a first-in first-out manner.

The scan driving part 250 outputs the second dummy scan signal SD_2 and seventh, eighth and ninth scan signals S7, S8 and S9 while the second dummy data signal DM_2 and the seventh, eighth and ninth line data signals 7L_DA, 8L_DA and 9L_DA are outputted to the seventh, eighth and ninth data lines DL7, DL8 and DL9.

The tenth, eleventh and twelfth line data signals 10L_DA, 11L_DA and 12L_DA that are delayed by the first, second and third dummy data signals DM_1, DM_2 and DM_3 are stored in the memory 217. The stored tenth, eleventh and twelfth line data signals 10L_DA, 11L_DA and 12L_DA are applied to the tenth, eleventh and twelfth data lines DL10, DL11 and DL12 during the vertical blanking period, respectively.

The controlling part 219 outputs the third dummy data signal DM_3 to the driving part 230 during the thirteenth data enable pulse DE_13. The tenth, eleventh and twelfth line data signals 10L_DA, 11L_DA and 12L_DA are synchronized with the third dummy data signal DM_3, and the synchronized tenth, eleventh and twelfth line data signals 10L_DA, 11L_DA and 12L_DA are applied to the driving part 230, in sequence.

Therefore, the third dummy data signal DM_3 and the tenth, eleventh and twelfth line data signals 10L_DA, 11L_DA and 12L_DA are applied to the data lines during the vertical blanking period, in sequence.

The scan driving part 250 outputs the third dummy scan signal SD_3 and tenth, eleventh and twelfth scan signals S10, S11 and S12 while the third dummy data signal DM_3 and the tenth, eleventh and twelfth line data signals 10L_DA, 11L_DA and 12L_DA are outputted to the tenth, eleventh and twelfth data lines DL10, DL11 and DL12.

According to this exemplary embodiment, a predetermined line ‘T’ representing a decreased charging rate is removed using dummy data signals and dummy scan signals in the N-line inversion method.

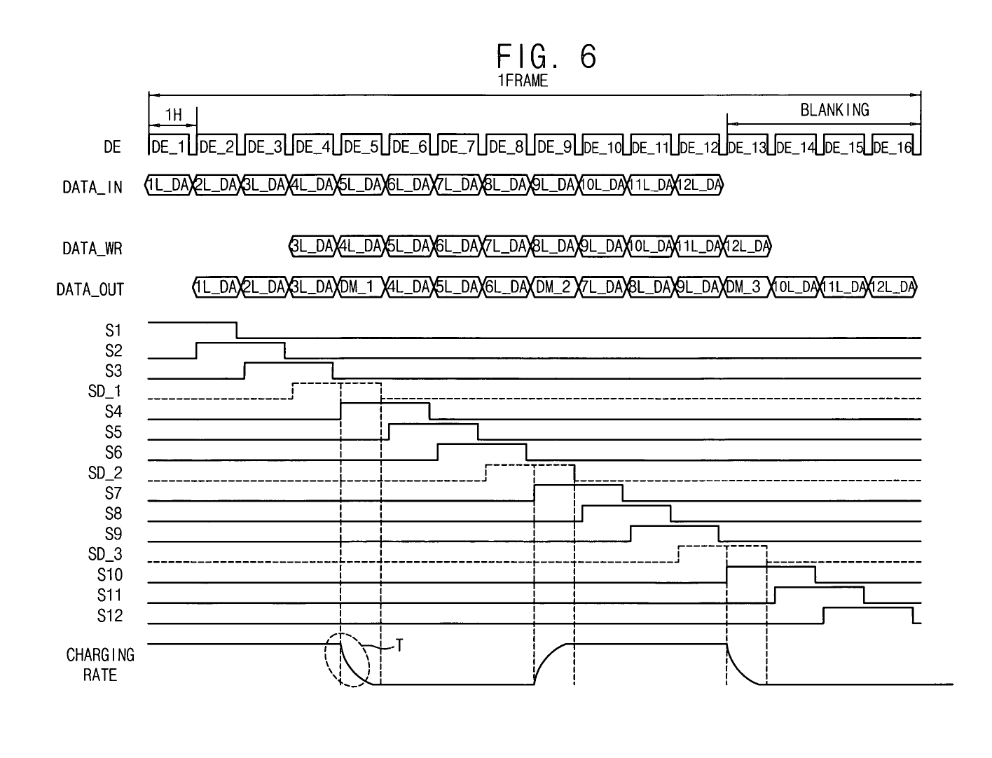

FIG. 6 is a timing diagram showing a method of driving a driving unit in accordance with another exemplary embodiment of the present invention. A driving unit of FIG. 6 is same as in FIGS. 1 to 5 except for a pulse width. Thus, the same reference numerals will be used to refer to the same or like parts as those described in FIGS. 1 to 5 and any further explanation will be omitted.

Referring to FIGS. 3, 4 and 6, a delayed data signal that is delayed by the dummy data signal is temporarily stored in a memory, and is operated during a blanking period. A pulse width of each scan signal is 2H, which corresponds to a time period for activating two scan lines adjacent to each other.

When the data driving part 230 outputs the second line data signal 2L_DA, the scan driving part 250 outputs the second scan signal S2 that is partially overlapped with the first scan signal S1 by 1H. The second scan signal S2 has a pulse width of 2H.

When pixels of a first horizontal line are charged by the first line data signal 1L_DA, pixels of a second horizontal line are pre-charged by the second scan signal S2 and the first line data signal 1L_DA. The second line data signal 2L_DA is then applied to the second scan line SL2 so that pixels of the second scan line SL2 are charged. Therefore, a charging rate of the pixels receiving data signals having a same polarity is increased by overlapping scan signals.

When the data driving part 230 outputs the first dummy data signal DM_1, the scan driving part 250 outputs the first dummy scan signal SD_1 that is partially overlapped with the third scan signal S3 by 1H. The first dummy scan signal SD_1 is not applied to one of the scan lines so that the first dummy data signal DM_1 is not charged in the pixels. Therefore, the charging rate of the pixels receiving inverted signals is increased by the first dummy scan signal SD_1.

When the data driving part 230 outputs the fourth line data signal 4L_DA, the scan driving part 250 outputs the fourth scan signal S4 that is partially overlapped with the first dummy data signal DM_1 by 1H.

According to this exemplary embodiment, a time delay is not formed between the third and fourth scan signals S3 and S4. In other words, the fourth scan signal S4 is not delayed with respect to the third scan signal S3 although the first dummy scan signal SD_1 is not applied to one of the scan lines.

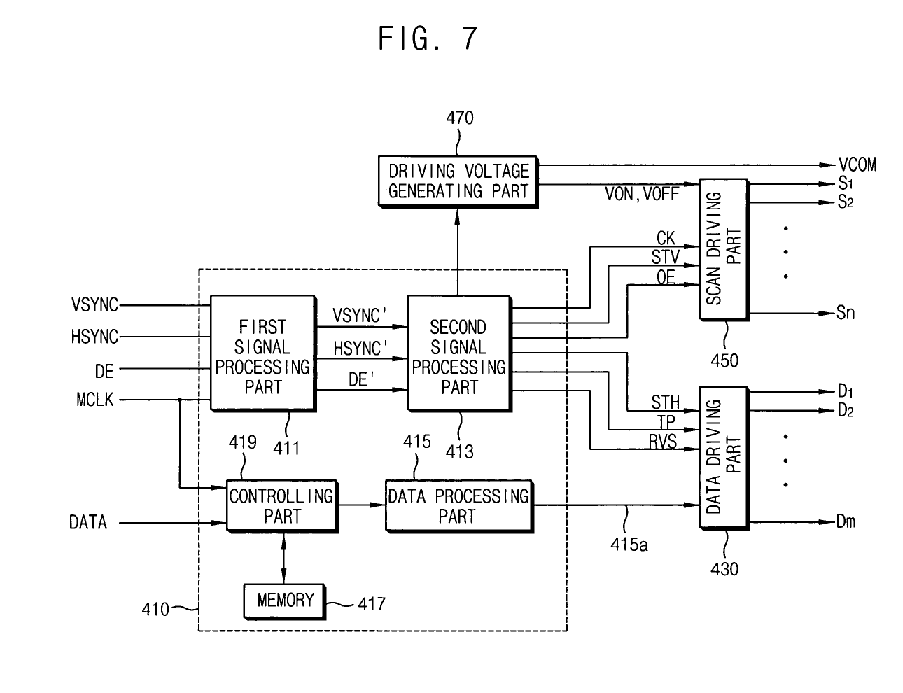

FIG. 7 is a block diagram showing a driving unit of an LCD device in accordance with another exemplary embodiment of the present invention.

Referring to FIG. 7, the driving unit includes a timing controlling part 410, a data driving part 430, a scan driving part 450 and a driving voltage generating part 470.

The timing controlling part 410 includes a first signal processing part 411, a second signal processing part 413, a data processing part 415, a memory 417 and a controlling part 419.

An external graphic controller (not shown) outputs first control signals to the first signal processing part 411. The controlling part 419 controls the first signal processing part 411 so that the first signal processing part 411 generates a second control signal for controlling dummy signals. The dummy signals are used in an N-line inversion method.

The first signal processing part 411 of an N-line inversion type driving unit modifies a data enable signal DE so that a number of clocks of a modified data enable signal DE′ corresponds to valid data signals and the dummy data signals. In this exemplary embodiment, the first signal processing part 411 includes a phase locked loop circuit to modify the data enable signal DE.

For example, when a number of scan lines and a number of line inversions are 800 and 32, respectively, a number of the dummy data signals is 800/32=25 so that a number of pulses of the data enable signal DE is changed from 800 into 825. Therefore, a portion of pulses of the modified data enable signal DE′ corresponding to each of the line inversions corresponds to 32 data signals and one dummy data signal. Thus, the portion of the pulses of the modified data enable signal DE′ corresponding to each of the line inversions is changed from 32 to 33.

The first signal processing part 411 also sends a modified horizontal synchronization signal HSYNC′ and a modified vertical synchronization signal VSYNC′ responsive to the horizontal synchronization signal HSYNC and the vertical synchronization signal VSYNC, respectively, to the second signal processing part 413.

In this exemplary embodiment, when the number of the scan lines and the number of line inversions are n and N, respectively, and n is a multiple of N, the number of the clocks is changed from n to n+(n/N−1). However, when n is not a multiple of N, the number of the clocks is changed from n into a truncated integer of n+(n/N) without decimals.

The second signal processing part 413 generates control signals that are applied to the data driving part 430, the scan driving part 450 and the driving voltage generating part 470, respectively, responsive to the modified data enable signal DE′ from the first signal processing part 411.

For example, the second signal processing part 413 generates a horizontal synchronization signal STH, a load signal TP, a scan clock signal CK, a vertical start signal STV that is a scan start signal, an inversion signal RVS, a scan output enable signal OE that is a gate output enable signal, etc.

The data processing part 415 processes data signals from the exterior graphic controller (not shown) to modify a timing and data of the data signals so that modified data signals 415a are applied to the data driving part 430.

The memory 417 temporarily stores the data signals. The controlling part 419 controls an operation of the memory 417 so that the memory 417 temporarily stores the data signals and the controlling part 419 reads stored data signals.

The data driving part 430 outputs the scan signals S1, S2, . . . Sn and the dummy scan signals to an LCD panel 190 of FIG. 3 responsive to the control signals such as the scan start signal STV, the scan output enable signal OE, the scan clock signal CK, etc., and the first and second voltages VOFF and VON from the driving voltage generating part 470.

The driving voltage generating part 470 generates the first and second voltages VOFF and VON and the common voltage VCOM. The first and second voltages VOFF and VON are applied to the scan driving part 450. The common voltage VCOM is applied to the liquid crystal capacitor CLC and the storage capacitor CS of the LCD panel 190 of FIG. 3.

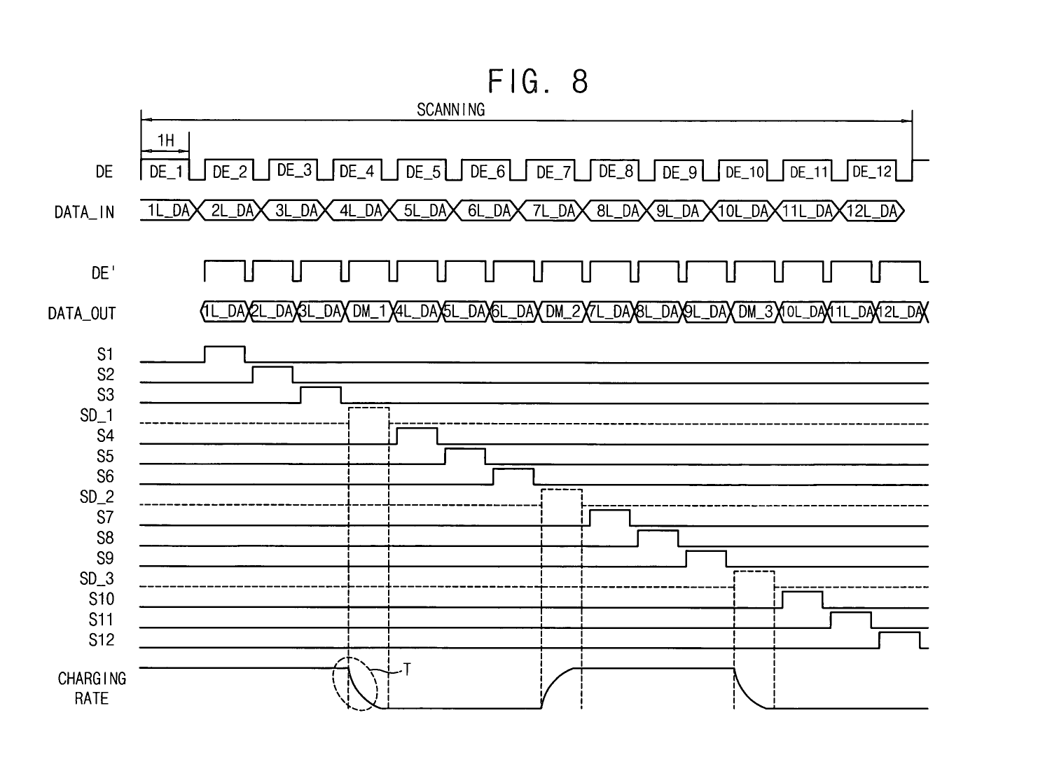

FIG. 8 is a timing diagram showing a method of driving a driving unit in accordance with another exemplary embodiment of the present invention. In this exemplary embodiment, a number of scan lines that are electrically connected to the driving unit is 12. A scanning period of a unit frame is 12H. The driving unit is operated through a 3-line inversion method.

Referring to FIGS. 3, 7 and 8, the first signal processing part 411 processes the data enable signal DE into the modified data enable signal DE′ for processing the dummy signals through the 3-line inversion method. Four pulses of the modified data enable signal DE′ correspond to three pulses of the data enable signal DE.

The controlling part 419 temporarily stores a first line data signal 1L_DA in the memory 417 during a first data enable pulse DE_1 being applied to the controlling part 419. The controlling part 419 reads the stored first line data signal 1L_DA and temporarily stores a second line data signal 2L_DA during a second data enable pulse DE_2 being applied to the controlling part 419. The controlling part 419 temporarily reads and stores the data enable pulses of the data enable signal DE, in sequence.

For example, an input line data signal DATA_IN is stored in the memory 417 responsive to the data enable signal DE, and an output line data signal DATA_OUT is outputted from the memory 417 responsive to the modified data enable signal DE′.

The controlling part 419 sequentially reads the first, second and third line data signals 1L_DA, 2L_DA and 3L_DA from the memory 417 responsive to the modified data enable signal DE′.

The data driving part 430 receives the first, second and third line data signals 1L_DA, 2L_DA and 3L_DA to output data signals having a first polarity with respect to a reference voltage responsive to the modified data enable signal DE′ to the first, second and third data lines DL1, DL2 and DL3, in sequence.

The scan driving part 450 outputs first, second and third scan signals S1, S2 and S3 that are synchronized with the first, second and third line data signals 1L_DA, 2L_DA and 3L_DA to the first, second and third scan lines.

When the third line data signal 3L_DA having the first polarity is applied to the third data line DL3, the controlling part 417 applies the first dummy data signal DM_1 to the data driving part 430. The data driving part 430 outputs a data signal having a second polarity responsive to the first dummy data signal DM_1 to one of the data lines DL1, DL2, . . . DL12. The second polarity is different from the first polarity with respect to the reference voltage. The scan driving part 450 generates a first dummy scan signal SD_1 that corresponds to the first dummy data signal DM_1. The first dummy scan signal SD_1 is not applied to the scan lines so that the first dummy data signal DM_1 does not operate the LCD panel 190 of FIG. 3.

The data driving part 430 then outputs fourth, fifth and sixth line data signals 4L_DA, 5L_DA and 6L_DA to fourth, fifth and sixth data lines DL4, DL5 and DL6, in sequence. The scan driving part 450 outputs fourth, fifth and sixth scan signals S4, S5 and S6 that are synchronized with the fourth, fifth and sixth line data signals 4L_DA, 5L_DA and 6L_DA to the fourth, fifth and sixth scan lines SL4, SL5 and SL6.

The data driving part 430 outputs the twelve line data signals 1L_DA, 2L_DA, . . . 12L_DA and three dummy data signals DM_1, DM_2 and DM_3 to the data lines DL1, DL2, . . . DL12 responsive to the modified data enable signal DE′. In addition, the scan driving part 450 generates the twelve scan signals S1, S2, . . . S12 and the three dummy scan signals, and applies the twelve scan signals S1, S2, . . . S12 to the scan lines SL1, SL2, . . . SL12.

According to this exemplary embodiment, a portion ‘T’ at which a charging rate is decreased is eliminated using the dummy data signal and the dummy scan signals so that a charging rate of the driving unit is uniformized.

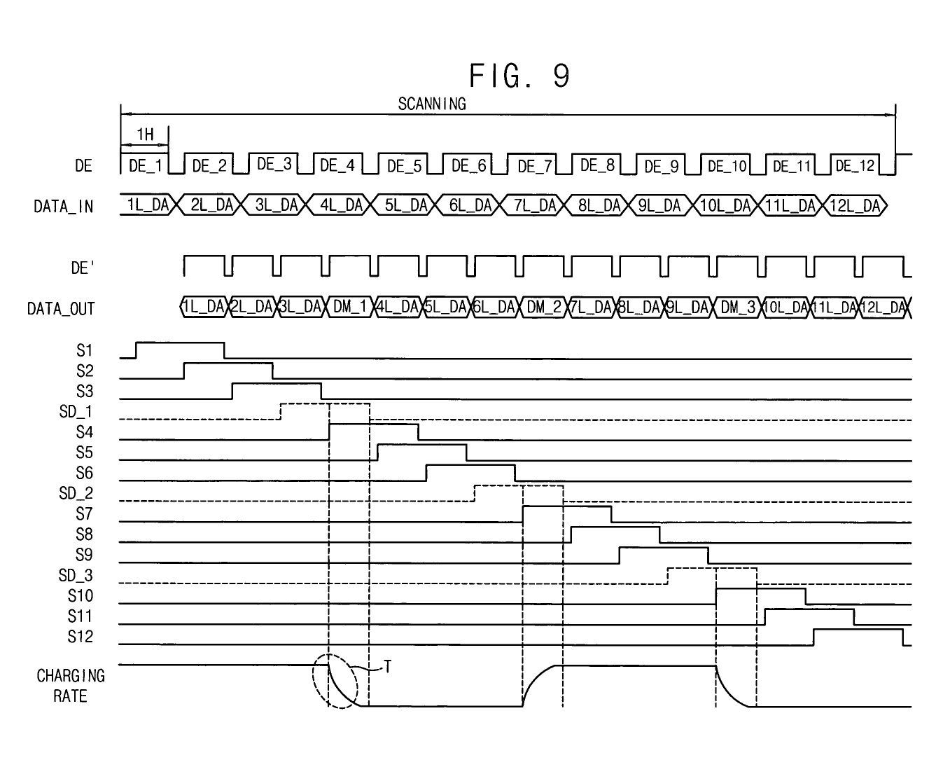

FIG. 9 is a timing diagram showing a method of driving a driving unit in accordance with another exemplary embodiment of the present invention. A driving unit of FIG. 9 is same as in FIG. 7. Thus, the same reference numerals will be used to refer to the same or like parts as those described in FIG. 7 and any further explanation will be omitted.

An operation of the driving unit of FIG. 9 is same as in FIG. 8 except a pulse width. Thus, the same reference numerals will be used to refer to the same or like parts as those described in FIG. 8 and any further explanation will be omitted. A pulse width of each of scan signals is 2H.

When the data driving part 430 outputs the second line data signal 2L_DA, the scan driving part 450 outputs the second scan signal S2 that is partially overlapped with the first scan signal S1 by 1H. The second scan signal S2 has a pulse width of 2H.

When pixels of a first horizontal line are charged by the first line data signal 1L_DA, pixels of a second horizontal line are pre-charged by the second scan signal S2 and the first line data signal 1L_DA. The second line data signal 2L_DA is then applied to the second scan line SL2 so that the pixels of the second scan line SL2 are charged. Therefore, the charging rate of the pixels receiving data signals having a same polarity is increased by overlapping the scan signals.

When the data driving part 450 outputs the first dummy data signal DM_1, the scan driving part 450 outputs the first dummy scan signal SD_1 that is partially overlapped with the third scan signal S3 by 1H. The first dummy scan signal SD_1 is not applied to one of the scan lines so that the first dummy data signal DM_1 is not charged in the pixels. Therefore, the charging rate of the pixels receiving inverted signals is increased by the first dummy scan signal SD_1.

When the data driving part 430 outputs a fourth line data signal 4L_DA, the scan driving part 450 outputs a fourth scan signal S4 that is partially overlapped with the first dummy data signal DM_1 by 1H.

According to this exemplary embodiment, a time delay is not formed between the third and fourth scan signals S3 and S4 that are adjacent to the first dummy scan signal SD_1. In other words, the fourth scan signal S4 is not delayed with respect to the third scan signal S3 although the first dummy scan signal SD_1 is not applied to one of the scan lines.

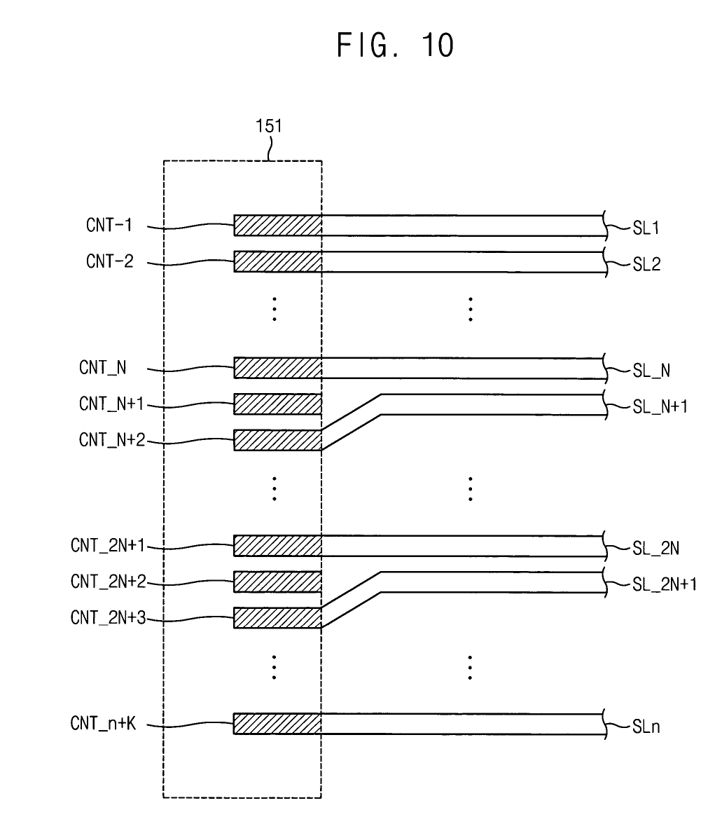

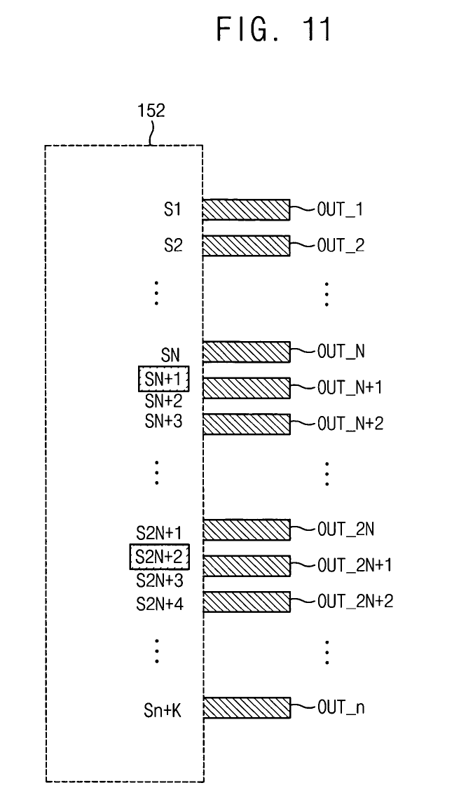

FIG. 10 is a plan view showing an exemplary scan driving part of FIG. 3. The scan driving part includes a scan driving integrated circuit (IC). The scan driving part is on an array substrate of the LCD panel 190.

Referring to FIG. 10, an IC pad 151 is formed adjacent to a side of the array substrate that has scan lines. The scan driving IC is mounted on the IC pad 151. The IC pad 151 includes a plurality of contact terminals CNT_1, CNT_2, . . . CNT_n+K that make contact with respective output terminals of the scan driving IC.

Selected ones of the contact terminals CNT_1, CNT_2, . . . CNT_n+K are electrically connected to corresponding ones of the scan lines SL1, SL2, . . . SLn. A number of the contact terminals is n+K in an N-line inversion method. The number of the dummy scan signals is K.

Nth contact terminal CNT_N is electrically connected to Nth scan line SL_N. (N+1)-th contact terminal CNT_N+1 is not electrically connected to one of the scan lines SL1, SL2, . . . SLn. In addition, (2N+2)-th contact terminal CNT_2N+2, (3N+3)-th contact terminal C NT_3N+3, . . . are not electrically connected to one of the scan lines SL1, SL2, . . . SLn.

The (N+1)-th contact terminal CNT_N+1, (2N+2)-th contact terminal CNT_2N+2, (3N+3)-th contact terminal CNT_3N+3, . . . of the IC pad 151 are electrically connected to the (N+1)-th output terminal, the (2N+2)-th output terminal, the (3N+3)-th output terminal, . . . of the scan driving IC, respectively. Therefore, (N+1)-th scan signal, (2N+2)-th scan signal, (3N+3)-th scan signal, . . . which are dummy signals are not applied to the LCD panel 190.

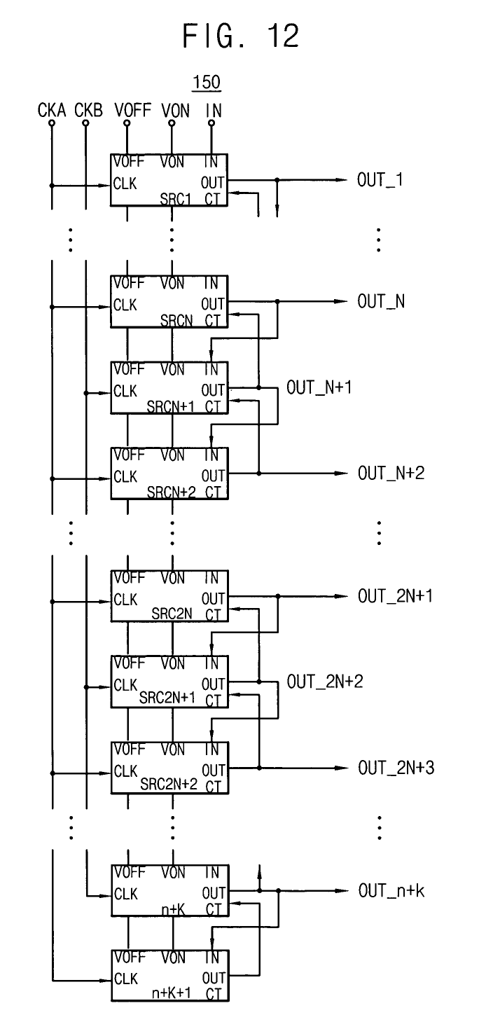

FIG. 11 is a plan view showing another exemplary scan driving part of FIG. 3.

Referring to FIG. 11, a scan driving IC 152 is formed adjacent to a side of the array substrate that has the scan lines. The scan driving IC 152 includes a plurality of output terminals OUT_1, OUT_2, . . . OUT_n that correspond to the scan lines SL1, SL2, . . . SLn, respectively. In this exemplary embodiment, a number of the output terminals OUT_1, OUT_2, . . . OUT_n is equal to a number of the scan lines SL1, SL2,

The scan driving IC 152 generates the scan signals S1, S2, . . . Sn and the dummy scan signals. The number of the dummy scan signals is K. The scan driving IC 152 outputs the scan signals S1, S2, . . . Sn to the scan lines SL1, SL2, . . . SLn. The scan driving IC 152 does not output the dummy scan signals.

For example, the scan driving IC 152 outputs N-th scan signal SN through N-th output terminal OUTN. The scan driving IC 152 does not output (N+1)-th scan signal SN+1. The scan driving IC 152 then outputs (N+2)-th scan signal SN+2 through (N+1)-th output terminal OUTN+1.

According to this exemplary embodiment, the scan driving IC 152 does not have output terminals for (N+1)-th scan signal, (2N+2)-th scan signal, (3N+3)-th scan signal, . . . which are dummy signals so that (N+1)-th scan signal, (2N+2)-th scan signal, (3N+3)-th scan signal, . . . are not outputted from the scan driving IC 152.

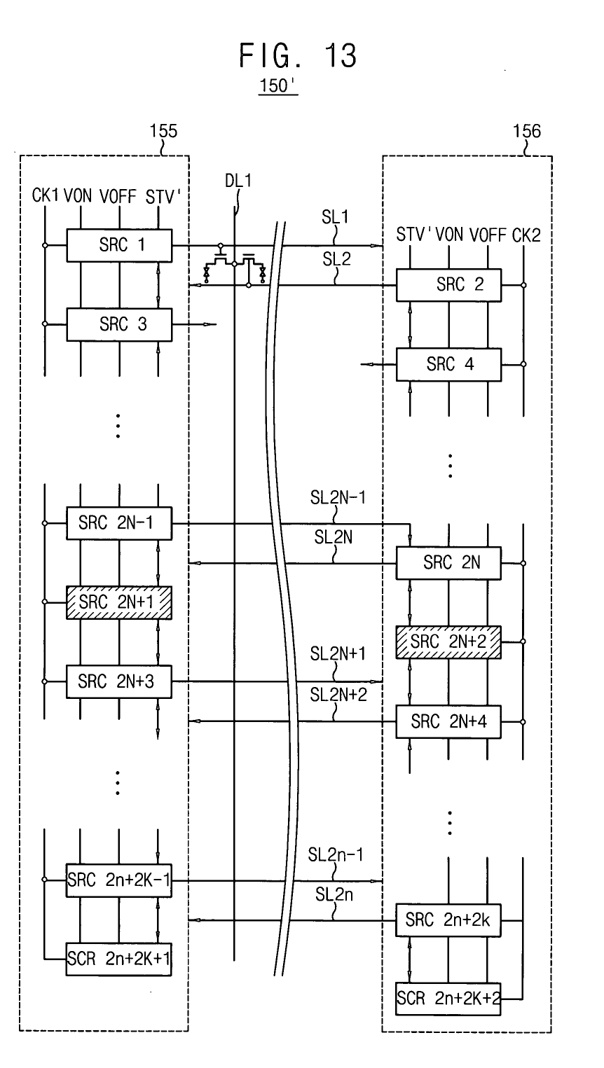

FIG. 12 is a plan view showing another exemplary scan driving part of FIG. 3. The scan driving part 150 is integrated on a portion of an array substrate. A switching element that is formed on the array substrate includes an amorphous-silicon thin film transistor (a-Si TFT). The a-Si TFT has a channel layer defined by an amorphous-silicon (a-Si) layer and an N+a-Si layer that is on the a-Si layer.

Referring to FIG. 12, the scan driving part 150 has a shift register including a plurality of stages SRC1, SRC2, . . . SRCn. The stages SRC1, SRC2, . . . SRCn are electrically connected in parallel with one another. An output terminal of each of the stages SRC1, SRC2, . . . SRCn is electrically connected to an input terminal of a next stage so that the stages SRC1, SRC2, . . . SRCn provide a parallel output shift register. Each of the stages SRC1, SRC2, . . . SRCn has a plurality of a-Si TFT.

A portion of the stages SRC1, SRC2, . . . SRCn+K correspond to the scan lines SL1, SL2, . . . SLn. A number of the stages SRC1, SRC2, . . . SRCn corresponding to the scan lines SL1, SL2, . . . SLn is n. A remaining portion of the stages SRC1, SRC2, . . . SRCn+K generate dummy scan signals. A number of the dummy stages SRC1, SRC2, . . . SRCK is K. The shift register further includes a control stage SRCn+K+1 that applies a control signal to the (n+K)-th stage that is a last stage of the stages SRC1, SRC2, . . . SRCn+K.

Each of the stages SRC1, SRC2, . . . SRCn+K includes the input terminal IN, the output terminal OUT, a control terminal CT, a clock input terminal CLK, a first voltage terminal VOFF and a second voltage terminal VON.

A scan start signal STV is applied to the input terminal IN of the first stage SRC1 as an operation start signal. An output signal of one of remaining stages SRC2, SRC3, . . . SRCn+K, which is a present stage, is applied to the input terminal IN of a next stage as the operation start signal. Alternatively, each of the stages SRC1, SRC2, . . . SRCn+K may further include a carry signal generating part that receives the output signal of the next stage as a carry signal so that the carry signal may be applied to the input terminal IN of a previous stage.

The scan lines SL1, SL2, . . . SLn are electrically connected to the output terminals OUT1, OUT2, . . . OUTn+K except (N+1)-th output terminal OUTN+1, (2N+2)-th output terminal OUT2N+2, . . . which are dummy output terminals. An odd stage clock signal CKA is applied to odd numbered stages SRC1, SRC3, . . . SRCn+K−1. An even stage clock signal CKB is applied to even numbered stages SRC2, SRC4, . . . SRCn+K. The odd and even stage clock signals CKA and CKB may have opposite phases to each other.

The output signal OUT of a next stage is applied to a control terminal CT of a present stage as a control signal. For example, a level of the output signal OUT of the present stage is changed into a low level by the control signal so that the present stage is reset.

In the N-line inversion method, output signals of (N+1)-th stage SRCN+1, (2N+2)-th stage SRC2N+2, . . . which are dummy stages are not applied to the scan lines SL1, SL2, . . . SLn. Each of the output signals of the dummy stages is only applied to the previous stage and the next stage as the control signal and the input signal IN, respectively. In other words, the output signals of the dummy stages are dummy signals.

According to this exemplary embodiment, the scan driving part 150 has the dummy stages so that a portion of the output signals of the stages SRC1, SRC2, . . . SRCn+K except the dummy stages SRCN+1, SRC2N+2, . . . are applied to the scan lines SL1, SL2, . . . SLn as the scan signals S1, S2, . . . Sn.

FIG. 13 is a plan view showing another exemplary scan driving part of FIG. 3.

Referring to FIG. 13, a scan driving part 150′ includes a first scan driving portion 155 and a second scan driving portion 156. The first scan driving portion 155 applies scan signals to odd numbered scan lines SL1, SL3, . . . SLn−1. The second scan driving portion 156 applies scan signals to even numbered scan lines SL2, SL4, . . . SLn. The first and second scan driving portions 155 and 156 are adjacent to sides of the LCD panel 190. In this exemplary embodiment, the first and second scan driving portions 155 and 156 are disposed adjacent to each other.

The first scan driving portion 155 has a shift register having first stages SRC1, SRC3, . . . SRC2n+2K+1. The first stages SRC1, SRC3, . . . SRC2n+2K−1 are electrically connected to one another, and in parallel with one another to provide a parallel output shift register. Output terminals of the first stages SRC1, 3 . . . SRC2n+2K−1 are electrically connected to odd numbered scan lines SL1, SL3, SLn−1, respectively.

The second scan driving portion 156 has a shift register having second stages SRC2, SRC4, . . . SRC2n+2K. The second stages SRC2, SRC4, . . . SRC2n+2K are electrically connected to one another, and in parallel with one another to provide a parallel output shift register. Output terminals of the second stages SRC2, SRC4, . . . SRC2n+2K are electrically connected to even numbered scan lines SL2, SL4, . . . SLn, respectively.

The first scan driving portion 155 includes a first control stage SCR2n+2K+1 that applies a control signal to a last stage SRC2n+2K−1 of the first scan driving portion 155. The second scan driving portion 156 includes a second control stage SCR2n+2K+2 that applies a control signal to a last stage SRC2n+2K of the second scan driving portion 156.

The first and second scan driving portions 155 and 156 are independently operated from each other. The first and second scan driving portions 155 and 156 are operated responsive to a modified scan start signal STV′ and first and second clock signals CK1 and CK2.

In this exemplary embodiment, the second clock signal CK2 that is applied to the second scan driving portion 156 is delayed by ½H with respect to the first clock signal CK1 that is applied to the first scan driving portion 155. The first and second scan driving portions 155 and 156 alternately output odd numbered scan signals and even numbered scan signals to the odd numbered scan lines SL1, SL3, . . . SL2n−1 and the even numbered scan lines SL2, SL4, . . . SL2n, respectively.

The first scan driving portion 155 further includes first dummy stages SRC2N+1, SRC4N+3, . . . SRC2KN+2K−1 that generate first dummy scan signals. A number of the first dummy stages SRC2N+1, SRC4N+3, . . . SRC2KN+2K−1 is K. The second scan driving portion 156 further includes second dummy stages SRC2N+2, SRC4N+4, . . . SRC2KN+2K that generate second dummy scan signals. A number of the second dummy stages SRC2N+2, SRC4N+4, . . . SRC2KN+2K is K.

Output terminals of the first and second dummy stages SRC2N+1, SRC2N+2, . . . SRC2KN+2K−1 and SRC2KN+2K are electrically disconnected from the scan lines so that output signals outputted from the first and second dummy stages SRC2N+1, SRC2N+2, . . . SRC2KN+2K−1 and SRC2KN+2K are dummy signals.

Each of the output signals outputted from the first dummy stages SRC2N+1, SRC4N+3, . . . SRC2KN+2K−1 is applied to a previous stage of the first scan driving portion 155 as a control signal and to a next stage of the first scan driving portion 155 as an input signal. Each of the output signals outputted from the second dummy stages SRC2N+2, SRC4N+4, . . . SRC2KN+2K is applied to a previous stage of the second scan driving portion 156 as a control signal and to a next stage of the second scan driving portion 156 as an input signal.

According to the present invention, the charging rate of each of inverted horizontal lines is uniformized in spite of a voltage drop in the N-line inversion method.

Therefore, although the display device displays high resolution and high frequency, an image display quality of the display device is improved. In addition, the display device displays a moving image.

This invention has been described with reference to the exemplary embodiments. It is evident, however, that many alternative modifications and variations will be apparent to those having skill in the art in light of the foregoing description. Accordingly, the present invention embraces all such alternative modifications and variations as fall within the spirit and scope of the appended claims.

What is claimed is:

1. An array substrate of an N-line inversion type comprising:
‘m’ number of data lines extended in a first direction;
‘n’ number of scan lines extended in a second direction that is substantially perpendicular to the first direction, each of the scan lines having a contact terminal that makes contact with corresponding ones of output terminals of a scan driving part that generates scan signals, a K(N+1)-th output terminal being disconnected from the scan lines; and
pixels formed in regions defined by the data and scan lines, a number of the pixels being m times n,
wherein m, n, K and N are each natural numbers.

2. The array substrate of claim 1, wherein an amorphous silicon transistor is disposed at each of the pixels, and the amorphous silicon transistor comprises a first electrode electrically connected to one of the data lines and a control electrode electrically connected to one of the scan lines.

3. The array substrate of claim 1, wherein the scan driving part comprises a shift register having stages to output signals of the stages to the scan lines responsive to a scan start signal, and the K(N+1)-th output terminal of K(N+1)-th stage is disconnected from the scan lines.

4. The array substrate of claim 3, wherein the shift register comprises amorphous silicon thin film transistors.

5. A display device comprising:
a display part having data lines, scan lines and pixels, each of the pixels being electrically connected to a corresponding one of the data lines and a corresponding one of the scan lines;
a driving part outputting valid data signals that charge the pixels and an invalid data signal to the data lines;
a scan driving part that generates scan signals corresponding to the valid data signals and an invalid scan signal corresponding to the invalid data signal to output the scan signals to the scan lines, the scan signals activating the scan lines corresponding to the valid data signals; and
a controlling part to control the data driving part so that the data driving part outputs N valid data signals having a first polarity, an invalid data signal having a second polarity and N valid data signals having the second polarity to the data lines, in sequence, the second polarity being opposite to the first polarity with respect to a reference voltage.

6. The display device of claim 5, wherein the invalid scan signal is disconnected from the scan lines so that the scan lines corresponding to the invalid data signal are deactivated.

7. The display device of claim 5, further comprising a storing part that stores a portion of the valid data signals, the portion of the valid data signals being delayed by the invalid data signal, and the controlling part reads the portion of the valid data signals that were stored in a first-in first-out manner to apply read valid data signals to the data driving part.

8. The display device of claim 7, wherein the controlling part controls the data driving part so that delayed valid data signals are applied to the data lines during a vertical blanking period, and the controlling part controls the scan driving part so that the scan signals corresponding to the delayed valid data signals are applied to the scan lines during the vertical blanking period.

9. The display device of claim 8, wherein a pulse width of each of the scan signals is 2H which corresponds to a time period for activating two scan lines adjacent to each other.

10. The display device of claim 9, wherein a pulse width of the invalid scan signal is 2H which corresponds to the time period for activating two scan lines adjacent to each other.

11. The display device of claim 5, further comprising a signal processing part that converts a first control signal from exterior to the driving part into a second control signal for processing the invalid data signal and the invalid scan signal, and the controlling part controls the data driving part and the scan driving part responsive to the second control signal.

12. The display device of claim 11, further comprising a storing part that temporarily stores the valid data signals responsive to the first control signal, and the controlling part reads the stored valid data signals in a first-in first-out manner to apply the read valid data signals to the data driving part.

13. A driving unit for driving a display device including a display part having data lines, scan lines and pixels electrically connected to the data and scan lines, the driving unit comprising:
a driving part to output valid data signals that charge the pixels and an invalid data signal to the data lines;
a scan driving part that generates scan signals corresponding to the valid data signals and an invalid scan signal corresponding to the invalid data signal to output the scan signals to the scan lines, the scan signals activating the scan lines corresponding to the valid data signals; and
a controlling part to control the data driving part so that the data driving part outputs N valid data signals having a first polarity, an invalid data signal having a second polarity and N valid data signals having the second polarity to the data lines, in sequence, the second polarity being opposite to the first polarity with respect to a reference voltage.

14. The driving unit of claim 13, wherein the invalid scan signal is disconnected from the scan lines so that the scan lines corresponding to the invalid data signal are deactivated.

15. The driving unit of claim 13, further comprising a storing part that stores a portion of the valid data signals, the portion of the valid data signals being delayed by the invalid data signal, and the controlling part reads the portion of the valid data signals that were stored in a first-in first-out manner to apply the portion of the valid data signals that have been read to the data driving part.

16. The driving unit of claim 15, wherein the controlling part controls the data driving part so that delayed valid data signals are applied to the data lines during a vertical blanking period, and the controlling part controls the scan driving part so that the scan signals corresponding to the delayed valid data signals are applied to the scan lines during the vertical blanking period.

17. The driving unit of claim 13, wherein a pulse width of each of the scan signals is 2H which corresponds to a time period for activating two scan lines.

18. The driving unit of claim 17, wherein a pulse width of the invalid scan signal is 2H which corresponds to the time period for activating two scan lines.

19. The driving unit of claim 13, further comprising a signal processing part that converts a first control signal from exterior to the driving part into a second control signal for processing the invalid data signal and the invalid scan signal, and the controlling part controls the data driving part and the scan driving part responsive to the second control signal.

20. The driving unit of claim 19, further comprising a storing part that temporarily stores the valid data signals responsive to the first control signal, and the controlling part reads stored valid data signals in a first-in first-out manner to apply read valid data signals to the data driving part.

21. A method of driving a display device including a display part having data lines, scan lines and pixels electrically connected to the data and scan lines, the method comprising:
applying N valid data signals to the data lines, and applying scan signals to the scan lines corresponding to the N valid data signals to activate the scan lines corresponding to the N valid data signals, the N valid data signals having a first polarity; and
applying an invalid data signal to one of the data lines after the N valid data signals, and applying an invalid scan signal to one of the scan lines corresponding to the invalid data signal to deactivate the one of the scan lines corresponding to the invalid data signal, the invalid data signal having a second polarity that is opposite to the first polarity with respect to a reference voltage.

22. The method of claim 21, further comprising temporarily storing a portion of valid data signals that are delayed by the invalid data signal.

23. The method of claim 22, wherein the portion of the valid data signals that are delayed are applied to the data lines during a vertical blanking period, and the scan signals corresponding to the delayed valid data signals are applied to the scan lines during the vertical blanking period.

24. The method of claim 21, wherein a pulse width of each of the scan signals is 2H which corresponds to a time period for activating two scan lines.

25. The method of claim 24, wherein a pulse width of the invalid scan signal is 2H which corresponds to a time period for activating two scan lines.

26. The method of claim 21, further comprising converting a first control signal provided from exterior to a driving unit of the display device into a second control signal for controlling application of the N valid data signals and the invalid data signal to the data lines.

27. The method of claim 26, wherein a number of the scan lines is ‘n’, a number of the valid data signals of one scanning period is ‘n’, a number of clocks of the first control signal of the one scanning period is ‘n’ and a number of clocks of the second control signal is a truncated integer of n+n/N without decimals.
